(19) United States
(12) Patent Application Publication
(10) Pub. No.: US 2010/0224237 A1
(43) Pub. Date: Sep. 9, 2010

(54) SOLAR CELL WITH BACKSIDE CONTACT NETWORK

(75) Inventor: James Chinmo Kim, Mountain View, CA (US)

Correspondence Address: Vierra Magen Marcus & DeNiro LLP, 575 Market Street, Suite 2500, San Francisco, CA, 94105, US

(73) Assignee: SUNDIODE INC., Sunnyvale, CA (US)

(21) Appl. No.: 12/397,841

(22) Filed: Mar. 4, 2009

(51) Int. Cl. H01L 31/00; H01L 31/0352

(52) U.S. Cl. 136/255; 136/256; 438/57; 257/E31.032

(57) ABSTRACT

A solar cell having back side contacts and method for forming the same is disclosed. A substrate of the solar cell has a first region that is n-doped and a second region that is p-doped. A first active region is above the n-doped region and a second active region is above p-doped region. A front region connects the top of the first active region to the top of the second active region to allow charge carriers to transfer from one active region to the other active region. The solar cell has a first conductive contact on the back side of the substrate and proximate the n-doped region and a second conductive contact on the back side of the substrate and proximate the p-doped region.

### FIELD OF THE INVENTION

The present invention relates to solar cell designs.

### BACKGROUND

Solar-cell technology is currently poised to make significant progress in mass adoption due in part to the looming shortage of traditional energy sources, e.g. crude oil and natural gas, and to the increased awareness of “green-technology” benefits. Solar-cell technology, though capturing “free” energy from the sun, has been expensive with per-watt ownership cost ($/W) far exceeding the cost per watt offered by electric utilities. Recently at $5/W, the pay-off period for a solar panel is as much as 50% of its lifespan, due largely to the expense of the semiconductor material used.

Semiconductor based solar cells pass solar radiation from a front side of the solar cell through an active region to a back side of the solar cell. Charge carriers are generated due to absorption of photons in the active region. The solar cell has two conductive contacts that are electrically connected to two different regions of the solar cell to allow a circuit to be formed for power generation based on the charge carrier creation. Typical solar cells have conductive contacts on both the front and rear sides of a solar cell to make electrical contacts to the cell. However, the front conductive contacts impede solar radiation from entering the solar cell, which is very detrimental to solar cell performance.

Silicon based solar cells having all of the conductive contacts on the back side (“back side contact solar cell”) have been proposed. These silicon based solar cells may comprise a monocrystaline silicon wafer. When solar radiation passes through the silicon wafer charge carriers are generated, which is the basis for generating power. Because back-side contact solar cells do not have a front side conductive contact to block incoming solar radiation, back-side contact solar cells have an efficiency advantage over those with front side conductive contacts. However, the monocrystaline silicon wafer may not be as efficient at generating charge carriers from solar radiation as other solar cell designs.

For example, solar cells have been proposed based on group III-V compound semiconductors. Such group III-V compound solar cells may be more efficient than solar cell designs such as those based on a monocrystaline silicon wafer. However, placing all of the conductive contacts on the back side of a group III-V multi-junction compound semiconductor solar cell presents challenges. There are challenges when placing back side contacts on other solar cell designs as well.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY

A solar cell having back side conductive contacts and method for forming the solar cell is disclosed. In some embodiments, the solar cell has separate active regions in which current flows in different directions. Current may flow upwards in one active region, through a portion of a front layer, and then downwards in a separate active region. In some embodiments, the active regions are nanostrucutres, such as nanocolumns, nanowires, nanorods, nanotubes. In some embodiments, the solar cell design is based on compound semiconductors that may include a group III element and a group V element.

One embodiment is a solar cell comprising the following. A substrate of the solar cell has a first region that is n-doped and a second region that is p-doped. A first active region is above the n-doped region and a second active region is above the p-doped region. An optically transparent and conductive or semiconductive region connects the top of the first active region to the top of the second active region to allow charge transfer. The solar cell has a first conductive contact on the back side of the substrate and proximate the n-doped region and a second conductive contact on the back side of the substrate and proximate the p-doped region.

One embodiment is a method of forming a solar cell comprising the following steps. A first region of a substrate is doped with an n-type dopant and a second region of the substrate is doped with a p-type dopant. A first active region is formed above the n-doped region and a second active region is formed above the p-doped region. A region that connects the top of the first active region to the top of the second active region is formed to allow charge transfer between the first and second active regions. A first conductive contact is formed on the back side of the substrate and proximate the n-doped region, and a second conductive contact is formed on the back side of the substrate and proximate the p-doped region.

One aspect is a solar cell comprising the following. The solar cell has a substrate in which first regions are n-type and second regions are p-type. The solar cell has a first plurality of active regions, each of which is over one of the n-type regions. The solar cell has a second plurality of active regions, each of which is over one of the p-type regions. An optically transparent region connects the tops of first active regions to the tops of the second active regions to allow charge transfer. The solar cell has a first plurality of conductive contacts on the back side of the substrate, each of which is proximate one of the n-type regions. The solar cell has a second plurality of conductive contacts on the back side of the substrate, each of which is proximate one of the p-type regions.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A depicts one embodiment of a solar cell with backside contacts in which the tops of the active regions are coalesced.

FIG. 1B depicts one embodiment of a solar cell with backside contacts in which the tops of the active regions are not coalesced.

FIG. 2A depicts one embodiment of a pattern for backside solar cell contacts.

FIG. 2B depicts one embodiment of a pattern for backside solar cell contacts.

FIG. 3 is a flowchart illustrating one embodiment of a process for forming a solar cell with backside contacts.

FIG. 4 is a flowchart illustrating one embodiment of a process for forming active regions of a solar cell with backside contacts.

FIG. 5 depicts one embodiment of a solar cell with backside contacts in a step pattern.

FIG. 6 depicts one embodiment of a multi-junction solar cell with backside contacts.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

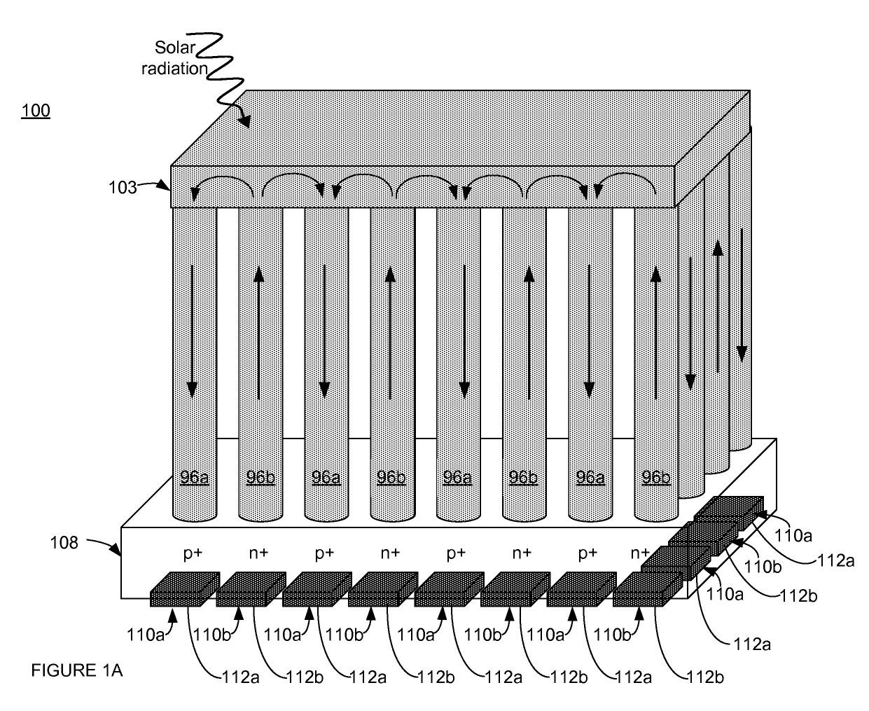

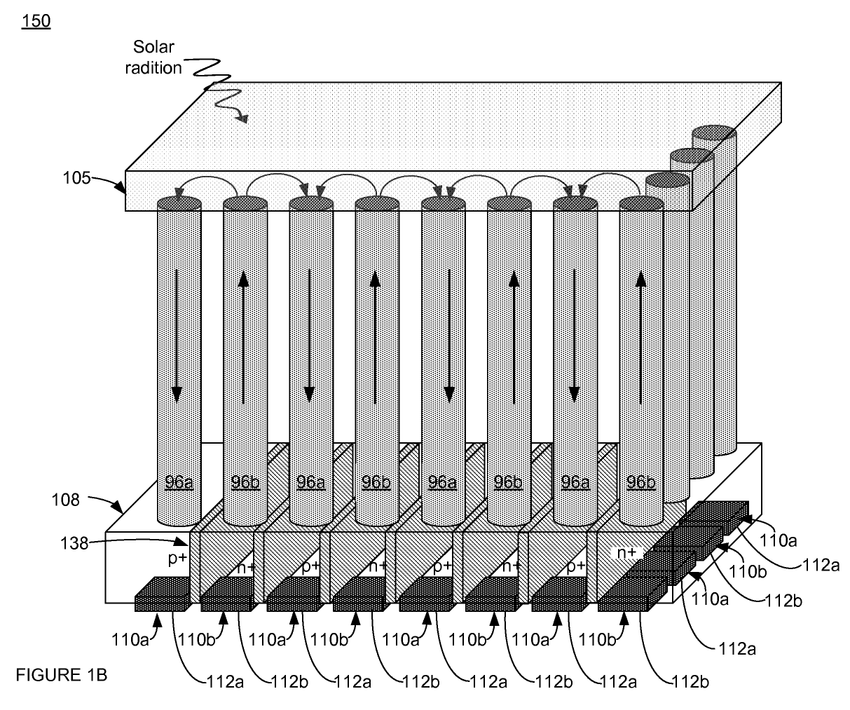

FIG. 1A is an example solar cell 100 having back side conductive contacts, in accordance with an embodiment of the present invention. The example solar cell 100 in general comprises a top or front layer 103, active regions 96a, 96b, a substrate 108, bottom conductive contacts 110a, 110b, and electrical leads 112a, 112b. Note that all of the conductive contacts 110a, 110b are on the bottom side of the solar cell 100. Therefore, none of the conductive contacts 110a, 110b blocks any of the incoming solar radiation in this embodiment. The contacts 110a, 110b may be made of a suitable metal, and do not need to be transparent. Therefore, all of the conductive contacts 110a, 110b may be optimized for high conductivity. That is, a trade off between transparency and conductivity does not need to be made for the conductive contacts. The front layer 103 serves to connect tops of adjacent active regions 96 to allow charge transfer between the tops of active regions 96. For example, front layer 103 electrically connects tops of active regions 96. However, note that the front layer 103 may be optimized for transparency.

Layer 103 is transparent to electromagnetic radiation in at least a portion of the spectrum. Solar radiation (e.g., photons) enters through layer 103 and may be absorbed in one of the active regions 96, which promotes an electron to the conduction band. Due to an electric field that will be described later, electrons promoted to the conduction band by the absorption of photons may flow resulting in a current. However, the current does not flow in the same direction in each of the active regions 96. As the arrows on the active regions 96a, 96b depict, current flows upward in active regions 96b and downward in active regions 96a.

Front layer 103 above the active regions 96a, 96b allows the current to flow out from the top of one active region 96b, through a portion of the front layer 103, and into the top of another active region 96a (as depicted by arrows in layer 103). In one embodiment, the front layer 103 may be made of a semiconducting material that is similar to at least some of the material in the active region 96. The current thus flows out of the solar cell 100 to electrical leads 112a and in to the solar cell 100 from electrical leads 112b.

The substrate 108 has alternating p-doped and n-doped regions. A given p-doped region resides between a contact 110a and an active region 96a. A given n-doped region resides between a contact 110b and an active region 96b. Examples of suitable materials for the substrate 108 include, but are not limited to, silicon (Si), germanium (Ge), silicon carbide (SiC), and zinc oxide (ZnO). If the substrate 108 is either Si, or Ge, the substrate 108 may be (111) plane oriented. If the substrate 108 is SiC, or ZnO, the substrate 108 may be (0001) plane oriented. An example of a p-type dopant for Si substrates includes, but is not limited to, boron (B). The p-type doping in the substrate may be p, p⁺ or, p⁺⁺. Examples of n-type dopants for Si substrates include, but are not limited to, arsenic (As) and phosphorous (P). The n-type doping in the substrate may be n, n⁺ or, n⁺⁺.

The n- and p-doping of the substrate 108 may create an inherent voltage drop across a pair of active regions 96a, 96b. This voltage drop creates a built in electric field across a pair of active regions 96a, 96b. Specifically, the electric field may go “upwards” in an active region 96a and “downwards” in an active region 96b. This built in electric field sweeps charge carriers that are created due to photon absorption, which causes a current in the directions indicated by the arrows on the active regions 96 (as well as layer 103). Two adjacent active regions 96a, 96b, the portion of layer 103 that connects them, and the p-doped and n-doped region of the substrate 108 below the two adjacent active regions 96a, 96b may be considered to be a U-shaped diode.

In some embodiments, the active regions 96 are doped, resulting in either a p-n device or an n-p device. For example, all of the active regions 96a and 96b may be n-doped or all of the active regions 96a and 96b may be p-doped. When the active regions 96 are doped, the doping may be light compared to the substrate 108 doping.

In some embodiments, the active regions 96 are not doped. Thus, the solar cell 100 may be considered to have p-i-n devices and/or n-i-p devices, each of which includes a p-doped region of the substrate, an active region 96a, a portion of layer 103, an active region 96b, and an n-doped region of the substrate. In this example, the p-doped region of the substrate 108 forms the base of a p-i-n device and the n-doped region of the substrate 108 forms the base of an n-i-p device.

Layer 103 may be doped to influence charge transfer or for other reasons. Layer 103 may be doped with n- or p-type dopants or may be co-doped with both n- and p-type dopants to achieve n type, p type, or insulating characteristics. When active regions 96 are n-doped, layer 103 may be n-doped or co-doped. When active regions 96 are p-doped, layer 103 may be p-doped or co-doped. If the active regions 96 are not doped, then layer 103 may be co-doped or undoped. Layer 103 may be doped more heavily than active regions 96. For example, the active regions 96 might be doped n, whereas layer 103 might be doped n, n⁺, or n⁺⁺.

In FIG. 1A, a row of eight active regions 96 and a column of four active regions 96 are depicted. There may be additional rows (and therefore columns) of active regions 96. However, those are not depicted in FIG. 1A so as to not obscure the diagram. Likewise, additional contacts 110a, 110b are not depicted to avoid cluttering the diagram. In one embodiment, there is a minimum of two active regions 96a, 96b—one which during operation conducts current upwards and the other which during operation conducts current downwards. There is no upper limit on the number of active regions 96a, 96b.

Each of the active regions 96a, 96b comprises one or more nanostructures, in one embodiment. The nanostructures may be nanocolumns, nanowires, nanorods, nanotubes, etc. In one embodiment, the nanostructures are formed from a material that comprises a group III-V compound semiconductor. As an example, the lateral width of the nanostructures may range from about 5 nm-500 nm. However, the lateral width of a nanostructure may be less than 5 nm and may be greater than 500 nm. Note that it is not required that each active region 96 be about the same width. In fact there may be a large variance in the widths of the nanostructures in a single solar cell 100. It is not required that the active regions 96 be nanostructures.

In the embodiment of FIG. 1A, the tops of the active regions 96a, 96b are coalesced into what is referred to as front layer 103. Front layer 103 is optically transparent for at least a portion of the electromagnetic spectrum. Further, at least some portions of front layer 103 are either conductive or semiconductive to allow current to flow between tops of active regions 96. Layer 103 may be formed from the same compound semiconductor as active regions 96a, 96b. In some embodiments, the layer 103 is doped. Because the spacing between active regions 96 is a design parameter, the distance in layer 103 that charge carriers travel can be made longer or shorter, as desired. This allows layer 103 to be optimized for transparency. In other words, because the conductive path in layer 103 can be made short, it is not required that layer 103 be optimized for high conductivity.

It is not required that the tops of the active regions 96a 96b be coalesced. FIG. 1B depicts one embodiment of a solar cell 150 in which the tops of the active regions 96a, 96 are not coalesced. In this embodiment, a substrate layer 105 is bonded to the tops of the active regions 96a, 96b. The substrate layer 105 is a high bandgap semiconductor in one embodiment. The substrate layer 105 serves as the conductive or semiconductive region that allows current to travel from one active region to another. The substrate layer 105 may be doped, and doping of substrate layer 105 may be similar to doping of layer 103. The n-type doping in the substrate 105 may be n, n⁺ or, n⁺⁺. The p-type doping in the substrate 105 may be p, p⁺ or, p⁺⁺. In some embodiments, substrate 105 is co-doped with n- and p-type dopants. For example, co-doping of substrate 105 may be used when the active regions 96 are not doped. The substrate 105 can be an indium-tin-oxide (ITO) grid, or an ITO sheet.

The embodiment depicted in FIG. 1B also shows insulating regions 138 in the substrate 108 that separate p-doped regions from n-doped regions. Insulating regions 138 prevent lateral conduction between doped regions. The insulating regions 138 are depicted as running from the front to the back of the substrate 108. Note that there may be other rows of active regions 96 (not depicted in FIG. 1B). The entire substrate 108 between two adjacent insulators 138 may be either n-doped or p-doped. Thus, the active regions 96 that are above this n-doped (or alternatively p-doped) region may all conduct current in the same direction. However, the substrate 108 can have alternating p-doping and n-doping from front to back, in which case there will be some active regions 96a that conduct current downwards and some active regions 96b that conduct current upwards in a given column. In this case, there may be additional insulating regions 138 that run perpendicular to the insulating regions 138 depicted in FIG. 1B in order to separate p-doped regions from n-doped regions. Note that it is not required that there be any insulating regions 138. Also note that while not shown in the embodiment of FIG. 1A, insulating regions 138 may be used in that embodiment as well. Example materials for the insulating regions 138 include, but are not limited to, SiO₂, and SiN. As an alternative to an insulating material an open trench can provide electrical isolation.

In one embodiment, each active region 96a, 96b comprises segments, each having a particular concentration of a “band gap altering element.” Layer 103 may also include one or more segments of the band gap altering element. As used herein, the term “band gap altering element” is any element whose concentration affects the band gap of the material into which it is incorporated. As an example, indium is a band gap altering element when incorporated into at least some group III-V compound semiconductors. As a particular example, the concentration of indium affects the band gap of InGaN. The indium replaces the gallium when it is incorporated into GaN. Thus, the formula for segments of the active regions 96 in some embodiments may be InₓGaₓ₋₁N. Indium may also affect the band gap of other III-V compound semiconductors.

In embodiments in which the nanostructures (and/layer 103) are segmented, the amount of band gap altering doping in the active region 96 can be non-uniform. For example, some segments may be heavily doped, other segments may be lightly doped, still others may be undoped. In one embodiment, the concentration of the indium in the active regions 96 is non-uniform such that the active regions have a number of energy wells, separated by barriers. The energy wells are capable of “absorbing” photons. The energy wells may be “graded”, by which it is meant that band gap of each energy well progressively decreases moving away from the front layer 103. Thus, the energy wells that are closer to the front layer 103 absorb photons that have energy that is at least as high as the band gap, but do not absorb photons having less energy. However, energy wells that are further from the front layer 103 are able to absorb photons having less energy.

Note that photons with a wavelength of about 365 nanometers (nm) have an energy of about 3.4 eV. Therefore, photons having a wavelength of 365 nm or shorter may be absorbed by a material having a band gap of 3.4 eV (e.g., GaN). Note that photons with a wavelength of about 1700 nanometers (nm) have an energy of about 0.7 eV. Therefore, photons of 1700 nm or shorter may be absorbed by a material having a band gap of 0.7 eV (e.g., InN). Further note that by having the In concentration increase from the front layer 103 (or substrate 105 in FIG. 1B) to the back of the solar cell, photons with increasingly less energy (longer wavelength) may be absorbed further from the front layer 103 or substrate 105.

A barrier between two energy wells has a higher band gap than those two energy wells, and will therefore not absorb photons whose energies are less than the barrier band gap. In other words, a photon must have a very short wavelength to be absorbed by a barrier. The barriers may serve to impede charge carriers from migrating between energy wells. However, charge carriers that are sufficiently energetic can “escape” the energy wells and be swept away as drift current (this drift current serves as the solar cell “output”).

In one embodiment, the layer 103 is formed from InGaN. In layer 103, the formula for the InGaN may be In_{y}Ga_{y-1}N, where y may be any value between 0 and 1. Layer 103 may comprise more than one sublayer, with the sublayers having different concentrations of indium. Note that layer 105 of FIG. 1B may also be formed from InGaN having the formula In_{y}Ga_{y-1}N, where y may be any value between 0 and 1. Likewise layer 105 may have more than one sublayer with differing concentrations of indium.

Further details of active regions 96 that are nanostructures formed from a group III-V compound semiconductor and are segmented with a bandgap altering material such as indium are discussed in published U.S patent application US 2008/0156366, titled “Solar Cell Having Active Regions with Nanostructures Having Energy Wells,” which is hereby incorporated by reference in its entirety for all purposes.

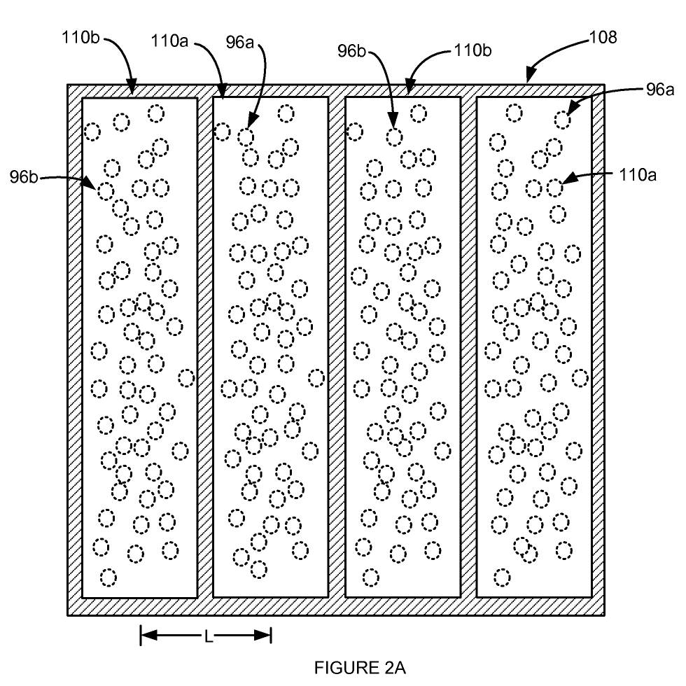

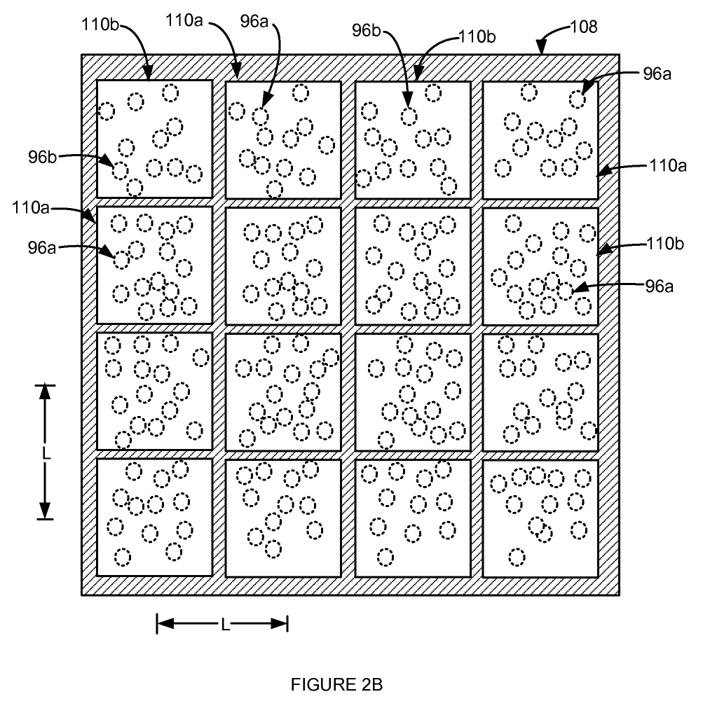

FIG. 2A depicts one embodiment of a back side contact layout. In general, four conductive contacts 110a, 110b are depicted on the back side of a substrate 108. The dashed circles 96a, 96b depict the relative locations of the active regions 96a, 96b with respect to the contacts 110a, 110b. Note that the active regions 96a, 96b are located over the front side of the substrate 108 similar to the embodiments depicted in FIG. 1A and FIG. 1B. However, in the embodiment depicted in FIG. 2A, there are many active regions 96a, 96b per each contact 110a, 110b. For example, many active regions 96a are located above the substrate 108 proximate to conductive contacts 110a. Likewise, many active regions 96b are located above the substrate 108 proximate to conductive contacts 110b. The active regions 96 may be nanostructures, although that is not required. Collectively, all of the nanostructures over one of the contacts may be considered to be a single active region 96.

The substrate 108 is p-doped near conductive contacts 110a and is n-doped near conductive contacts 110b. For example, the portion of the substrate 108 that is between contacts 110a and active regions 96a is n-doped and the portion of the substrate 108 that is between contacts 110b and active regions 96b is p-doped. Thus, during operation of the solar cell 100, current flows out of the solar cell 100 for conductive contacts 110a that are near the p-doped regions and current flows into the solar cell 100 for conductive contacts 110b that are near the n-doped regions.

The distance “L” between the midpoints of two adjacent contacts 110a and 110b may be selected based on lateral resistance in the layers 103 (FIG. 1A) and/or layer 105 (FIG. 1B). Specifically, current should flow from the top of active regions 96b to the top of active regions 96a. Selection of the distance L affects the distance that current travels in layer 103 or 105 between the tops of the active regions 96a, 96b. Note that the layers 103, 105 can be made very transparent at the expense of conductivity. If losses due to lateral resistance are higher than desired for a material with a given transparency and lateral resistance, then the distance L can be reduced. On the other hand, the distance L can be made greater if greater losses due to lateral resistance are acceptable or if the material can be made more laterally conductive without sacrificing transparency by more than a desired amount. Increasing L may allow fewer contacts 110 to be used.

FIG. 2B depicts one embodiment of an example of back side contact layout. In general, sixteen conductive contacts 110a, 110b are depicted on the back side of a substrate 108. The dashed circles 96a, 96b depict the relative locations of the active regions 96a, 96b with respect to the contacts 110a, 110b. The substrate 108 is p-doped near conductive contacts 110a and is n-doped near conductive contacts 110b. In this embodiment, a given contact 110a has neighbor contacts 110b to the right, left, above, and below (unless near an edge). However, this pattern is not a requirement. Other layouts, possibly of non-repeating patterns (e.g. spiraling patterns), may also be utilized for improved efficiency and/or for other benefits.

The contacts 110a, 110b may reflect at least a portion of the solar radiation that was not absorbed back into the active regions 96. In some embodiments, the contacts 110a, 110b are optimized to reflect unabsorbed solar radiation back into the active regions 96.

In one embodiment, the contacts 110 may be electrically connected to other contacts in parallel or series to obtain desired output voltage. A pair of adjacent contacts 110a, 110b can be thought of as the contacts of a “micro solar cell.” By selecting how the micro solar cells are connected (e.g., series, parallel) voltage and current characteristics can be set to desired levels. For example, in the embodiment depicted in FIG. 1A a series connection may be formed by electrically connecting two adjacent contacts 110a and 110b and removing the leads 112a, 112b of the connected contacts. Such a series contact may serve to increase the voltage difference between the contacts 110a and 110b that are neighbors to the connected contacts. An advantage of the series connection may be increased efficiency due to reduced Joule heating. Another advantage may be the ability to tailor output voltage to a particular application. A parallel connection may be formed by connecting two contacts 110a together and separately connecting two contacts 110b together. In this example, there would no longer be need for a lead 112a from each of the contacts 110a. Therefore, one of the leads 112a is removed with reference to FIG. 1A.

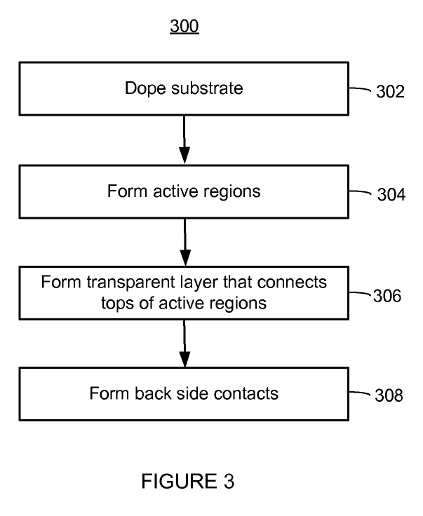

FIG. 3 is a flowchart of one embodiment of a process 300 for forming a solar cell with back side contacts. In step 302, a substrate 108 is doped to create p-doped regions and n-doped regions. In some embodiments, the doped regions form one part of a p-i-n or n-i-p device. Example patterns for the doping have been discussed herein, but process 300 is not limited to those patterns. In one embodiment, the doping is performed using ion implantation to allow for great precision in the doping of the substrate 108. However, ion implantation is not required. In one embodiment, the doping may involve diffusion of dopant material pattern-pasted on the substrate 108. An example of a p-type dopant for Si substrates includes, but is not limited to, boron (B). The p-type doping may be p, p⁺ or, p⁺⁺. Examples of n-type dopants for Si substrates include, but are not limited to, arsenic (As) and phosphorous (P). The n-type doping may be n, n⁺ or, n⁺⁺. Note that the doping of the substrate 108 can be performed later in process 300. For example, the substrate 108 can be doped after the active regions 96 are formed. Also note that the doping can be performed from the front side, the back side or both.

In step 304, active regions 96a, 96b are formed above the substrate 108. In one embodiment, the active regions 96a, 96b are grown. For example, one or more active regions 96 are grown above each p-doped region and each n-doped region. Active regions 96a and 96b may each be formed of the same material and using the same process steps. In one embodiment, the active regions 96 are nanostructures. The nanostructures may be grown either by self-assembly or by patterned growth using epitaxial growth techniques such as metalorganic chemical vapor deposition, molecular beam epitaxy, and hydride vapor phase epitaxy. In patterned growth, a portion of the substrate surface which is not covered by mask material such as SiO₂ or SiNₓ is exposed to serve as nucleation sites for the nanostructures. The top of the active regions 96 may or may not be coalesced. Thus, in one embodiment, growth conditions are such that the nanostructures coalesce at the top. Note that it is not required that the active regions 96 be nanostructures.

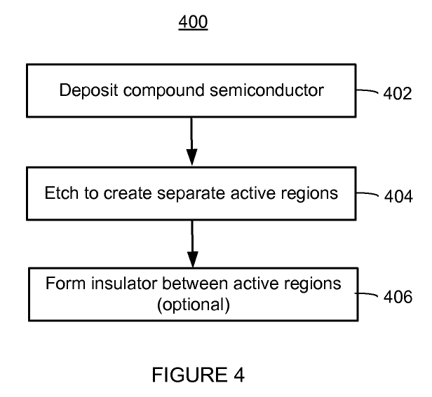

FIG. 4 depicts an alternative implementation of forming the active regions 96. FIG. 4 describes one embodiment of a process 400 for forming the active regions 96 that are not nanostructures. Process 400 is one implementation of step 304 of process 300. In step 402, a material for the active regions 96 is deposited above the substrate 108. In one embodiment, the material is a group III/V compound semiconductor. However, another material may be used.

In step 404, the material that was deposited in step 402 is etched to create separate active regions 96. In one embodiment, a single active region 96b is formed above each of the n-doped regions of the substrate 108 and a single active region 96a is formed above each of the p-doped regions of the substrate 108. However, multiple active regions 96 may be formed over a single doped region of the substrate 108. In optional step 406, an insulator is formed between the active regions 96. Example insulators include, but are not limited to, SiO₂ and SiNₓ. Note that the insulator material is not a requirement as an empty trench may also provide isolation between adjacent active regions 96.

Returning now to the discussion of process 300, in step 306, a transparent layer that electrically connects tops of active regions 96a, 96b is formed. There are a variety of ways of forming the transparent layer. In one embodiment, the active regions 96 are formed such that the tops are coalesced (e.g., layer 103 of FIG. 1A). In such an embodiment, the coalesced portion 103 can be treated to achieve the desired conductivity between the tops of active regions 96, while maintaining the desired transparency.

In one embodiment, a layer 105 is formed above the tops of the active regions 96 to serve as the transparent layer that electrically connects the tops of active regions 96. For example, substrate layer 105 is bonded to the tops of active regions 96. In some embodiments, the bonding is achieved by pressing layer 105 onto active regions 96 with an appropriate force and at a suitable temperature. Techniques for bonding materials together are known and will not be discussed in detail. In some embodiments, layer 105 is ITO.

The desired conductivity may be achieved by doping the coalesced portion 103 or substrate 105 above the active regions 96. For example, an n-dopant can be implanted over all of the tops of the active regions 96a, 96b. Alternatively, a p-dopant can be implanted over all of the tops of the active regions 96a, 96b. In some embodiments, both n- and p-type doping is performed in coalesced portion 103 (or layer 105). In this co-doping example the level of n-type carriers due to n-dopant can be equal to the level of p-type carriers due to p-dopant, but that is not a requirement. Co-doping can be used to achieve a certain growth mode (e.g., coalescence) while preserving intrinsic or very light level of p- or n-doping characteristics.

In step 308, back side contacts 110a, 110b are formed. The back side contacts 110a, 110b may be formed of a suitable metal such as aluminum, copper, tungsten or any other suitable metal. However, it is not a requirement that the contacts 110 be formed of a metal as another conductive material might be used. In one embodiment, the back side contacts 110a, 110b are formed by depositing a metal, patterning, and etching to achieve the desired contact pattern. Contacts 110a and 110b may be formed at the same level, but this is not a requirement.

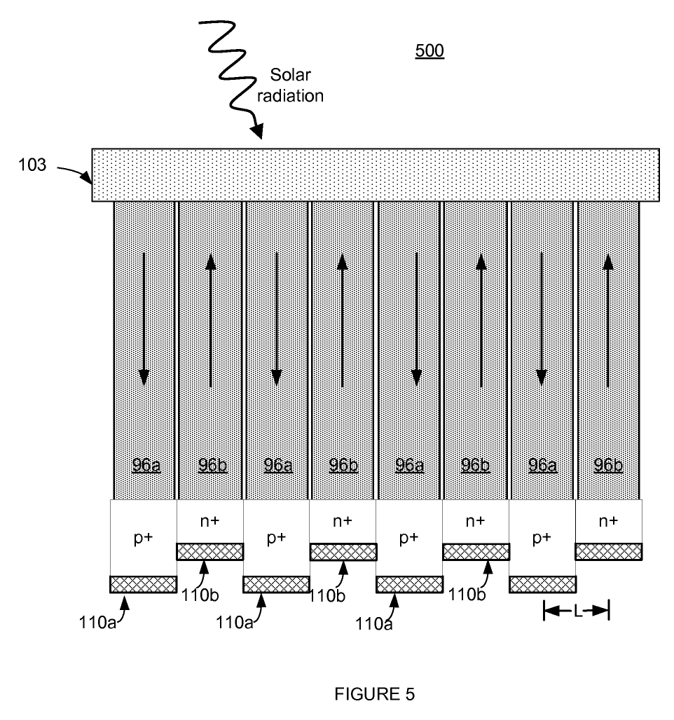

In one embodiment, the back side contacts 110a, 110b have a step pattern, such as the embodiment depicted in FIG. 5. FIG. 5 depicts one embodiment of a solar cell 500 having back side contact in a step pattern. In this example, contacts 110b are slightly recessed with respect to contacts 110a. As an alternative, contacts 110a may be slightly recessed with respect to contacts 110b. This step pattern provides for electrical isolation between contacts 110a and 110b, while not requiring any lateral spacing or insulation between contacts 110a and 110b. Therefore, the contacts 110a and 110b may cover a greater portion of the backside of the solar cell. Note that what is depicted in FIG. 5 as an active region 96a may be one or more nanostructures. For example, there may be a single, a few, tens, hundreds, thousands, or even more nanostructures in a single active region 96a (likewise for an active region 96b). Eliminating insulating regions or trenches (see 138 FIG. 1B) between contacts 110a, 110b allows more efficient use of the available active structures 96a, 96b.

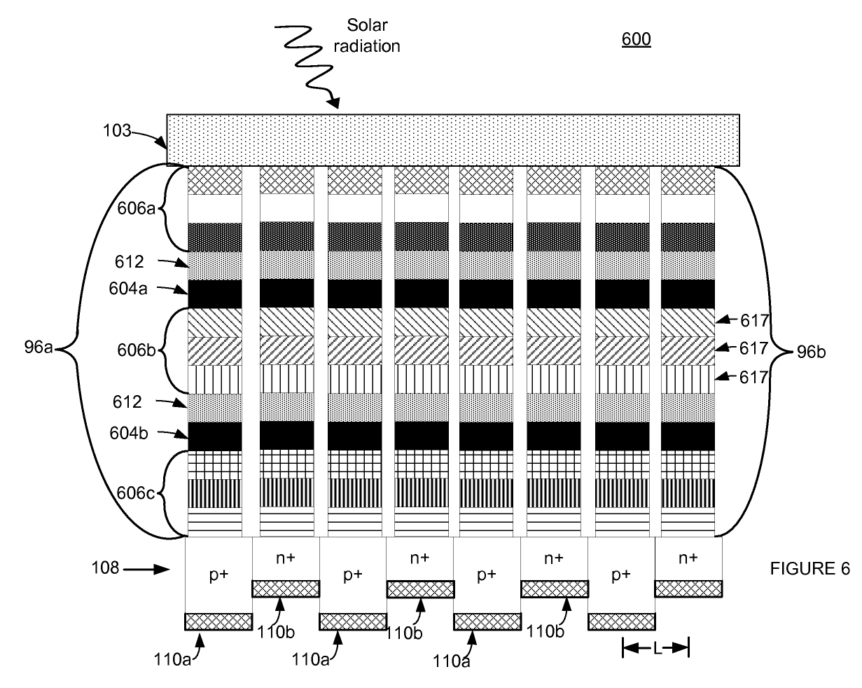

In one embodiment, a particular active region 96 of the solar cell has one or more tunnel junctions to achieve multi-junction device structure. FIG. 6 illustrates an example multi-junction device 600, in accordance with an embodiment of the present invention. In general, the solar cell 600 has front layer 103, alternating active regions 96a, 96b, substrate 108, and bottom contacts 110a, 110b. Electrical leads are not depicted in FIG. 6 so as to not obscure the diagram. Each of the active regions 96a, 96b includes sub-regions 606a, 606b, 606c, junction layers 604a, 604b, and tunnel junctions 612. The active regions 96 may comprise InGaN, although other materials might be used.

Each of the sub-regions 606 may be configured for absorption of photons of different ranges of wavelengths. For example, a first sub-region 606a may be configured to absorb photons from 365 nm to R nm, a second sub-region 606b may be configured to absorb photons from R nm to S nm, and a third sub-region 606c may be configured to absorb photons from S nm to 1700 nm.

Series connection of the three sub regions 606 is achieved by two tunnel junctions 612. The tunnel junctions 612 may be grown in the device 600 so the device 600 may be monolithic. As an alternative to device 600 more or fewer sub regions 606 and tunnel junctions 612 may be used.

In the embodiment depicted in FIG. 6, each of the sub-regions 606 is divided into three segments 617. Each segment 617 has a different concentration of a band gap altering element (e.g., indium) to achieve the desired wavelength absorption for that segment 617. However, it is not required that the sub-regions 606 be segmented. In an embodiment in which the sub-regions 606 themselves are not segmented, each sub-region 606 has a different concentration of a band gap altering element (e.g., indium) to achieve the desired wavelength absorption for that sub-region 606. In the example of FIG. 6, sub-regions 606a-606c may be formed as a monolithic device structure with tunnel junctions. In another embodiment, sub-regions 606 are bonded together rather than growing them at the same time.

In some embodiments, the substrate 108 is made reflective such that photons that are not absorbed in the active regions 96a, 96b are reflected back to the active regions. A reflective substrate may be used with any of the examples discussed herein. For example, referring again to FIG. 1A, the substrate 108 (e.g., Si) may be etched to generate porous Si that diffusely reflects unabsorbed photons back towards the active regions 96a, 96b. Because making the substrate 108 porous may reduce vertical conductivity, the substrate 108 may be made partially porous.

In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1 A solar cell comprising:
a substrate having a front side and a back side, wherein the substrate has a first region that is n-doped and a second region that is p-doped;
a first active region above the n-doped region of the substrate, wherein the first active region has a top;
a second active region above the p-doped region of the substrate, wherein the second active region has a top;
a front region that connects the top of the first active region to the top of the second active region to allow charge carriers to transfer from one of the active regions to the other active region;
a first conductive contact on the back side of the substrate and proximate the n-doped region; and
a second conductive contact on the back side of the substrate and proximate the p-doped region.

2. The solar cell of claim 1, wherein the top of the first active region is coalesced with the top of the second active region to form the front region.

3. The solar cell of claim 1, wherein the first active region, the second active region, and the front region are all either p-doped or n-doped.

4. The solar cell of claim 1, wherein the first active region and the second active region are not doped and the front region is co-doped with both an n-type dopant and a p-type dopant.

5. The solar cell of claim 1, wherein the first active region and the second active region each comprise a plurality of nanostructures.

6. The solar cell of claim 1, wherein the first active region and the second active region are electrically isolated from each other between the substrate and the front region.

7. The solar cell of claim 1, wherein the first active region and the second active region are each formed from a group III-V compound semiconductor.

8. The solar cell of claim 1, wherein the n-doped region of the substrate and the p-doped region of the substrate create an electric field across the first active region and the second active region, the electric field sweeps charge carriers that are created from photon absorption in the active regions upwards in one of the active regions and downwards in the other active region, the charge carriers pass through the front region.

9. A method of forming a solar cell, said method comprising:
doping a first region of a substrate with an n-type dopant;
doping a second region of the substrate with a p-type dopant, wherein the substrate has a front side and a back side;
forming a first active region above the n-doped region of the substrate, wherein the first active region has a top;
forming a second active region above the p-doped region of the substrate, wherein the second active region has a top;
forming a front region that connects the top of the first active region to the top of the second active region to allow charge carriers to transfer from one of the active regions to the other active region;
forming a first conductive contact on the back side of the substrate and proximate the n-doped region; and
forming a second conductive contact on the back side of the substrate and proximate the p-doped region.

10. The method of forming a solar cell of claim 9, wherein forming the front region includes growing the first active region and the second active region such that they are coalesced.

11. The method of forming a solar cell of claim 9, wherein the first active region and the second active region are electrically isolated from each other between the substrate and the front region.

12. The method of forming a solar cell of claim 9, wherein forming the first active region, forming the second active region, and forming the front region includes incorporating n-doping into the first active region and the second active region, and co-doping the front region with both n-doping and p-doping.

13. The method of forming a solar cell of claim 9, wherein forming the first active region, forming the second active region, and forming the front region includes incorporating either p-doping or n-doping into each of the first active region, the second active region, and the front region.

14. The method of forming a solar cell of claim 9, wherein forming the first active region and forming the second active region includes growing a plurality of nanostructures.

15. The method of forming a solar cell of claim 9, wherein forming the first active region and forming the second active region includes:
depositing a material; and
etching the material to form the first active region and the second active region.

16. A solar cell comprising:
a substrate having a front side and a back side, wherein the substrate has a first plurality of regions that are n-type conductivity and a second plurality of regions that are p-type conductivity, wherein each of the regions of one of the conductivity types is adjacent to at least one of the regions of the other conductivity types;
a first plurality of active regions, wherein each active region of the first plurality of active regions is over one of the n-type regions and has a top;
a second plurality of active regions, wherein each active region of the second plurality of active regions is over one of the p-type regions and has a top;
an optically transparent region that connects the tops of active regions of the first plurality to the tops of active regions of the second plurality to allow charge transfer;
a first plurality of conductive contacts exposed on the back side of the substrate, each contact of the first plurality of contacts is proximate one of the n-type regions; and
a second plurality of conductive contacts exposed on the back side of the substrate, each contact of the second plurality of contacts is proximate one of the p-type regions.

17. The solar cell of claim 16, wherein the tops of the first plurality of active regions and the tops of the second plurality of active regions are coalesced to form the optically transparent region.

18. The solar cell of claim 16, wherein the first active regions are lightly n-doped, the second active regions are lightly n-doped and the optically transparent region is one of lightly n-doped, moderately n-doped, or heavily n-doped.

19. The solar cell of claim 16, wherein the first active regions are lightly p-doped, the second active regions are lightly p-doped and the optically transparent region is one of lightly p-doped, moderately p-doped, or heavily p-doped.

20. The solar cell of claim 16, wherein each active region of the first plurality of active regions and each active region of the second plurality of active regions comprise a plurality of nanostructures.

21. The solar cell of claim 16, wherein current due to charge carriers that are created from photon absorption in the first and second active regions travels upwards in one of the first active regions, through a portion of the optically transparent region, and downwards in an adjacent second active region.

22. The solar cell of claim 16, wherein each active region of the first plurality of active regions and each active region of the second plurality of active regions are electrically isolated from each other between the substrate and the optically transparent region.

23. The solar cell of claim 16, wherein one of the first active regions and an adjacent one of the second active regions forms part of a micro solar cell, and wherein ones of the first plurality of contacts are electrically connected to adjacent ones of the second plurality of contacts to connect micro solar cells in series.

24. The solar cell of claim 16, wherein one of the first active regions and an adjacent one of the second active regions forms part of a micro solar cell, and wherein: at least two of the first plurality of contacts are electrically connected together; and at least two of the second plurality of contacts are electrically connected together to form a parallel connection of a micro solar cell.
